(19) United States
(12) Patent Application Publication
(10) Pub. No.: US 2014/0375185 A1
(43) Pub. Date: Dec. 25, 2014

(54) ELECTRONIC DEVICE ENCLOSURE WITH COVER

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventor: ZHAN-YANG LI, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/256,456

(22) Filed: Apr. 18, 2014

(30) Foreign Application Priority Data
Jun. 24, 2013 (CN) 2013102520561

(51) Int. Cl. H05K 5/02

(52) U.S. Cl. CPC H05K 5/0221
USPC 312/223.1

(57) ABSTRACT

An electronic device enclosure including a housing and a cover conveniently assembled with the housing is disclosed. The cover includes an installation member engaged in an installation hole defined in the housing. The blocking member is secured to the cover and comprises a blocking piece. The operation member is slidable relative to the blocking member between a locked position, where the blocking piece extends into the positioning hole and resists an edge of a positioning hole defined in the housing, preventing the installation member from disengaging from the installation hole; and an unlocked position, where the blocking piece is disengaged from the positioning hole, allowing the installation member to be disengaged from the installation hole.

### FIELD

Embodiments of the present disclosure relate to electronic device enclosures, and particularly to an electronic device enclosure with a cover.

### BACKGROUND

An electronic device enclosure generally includes a housing configured for receiving a number of electronic components and a cover secured to the housing, the cover is configured for preventing dust from flowing into the housing and preventing the electronic components from being damaged.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an electronic device enclosure.

FIG. 2 is an enlarged view of a circled portion II of FIG. 1.

FIG. 3 is an exploded, isometric view of a cover, an operation member, and a blocking member of the electronic device enclosure of FIG. 1.

FIG. 4 is an assembled, isometric view of the cover, the operation member, and the blocking member of the electronic device enclosure of FIG. 3.

FIG. 5 is an assembled, isometric view of the electronic device enclosure of

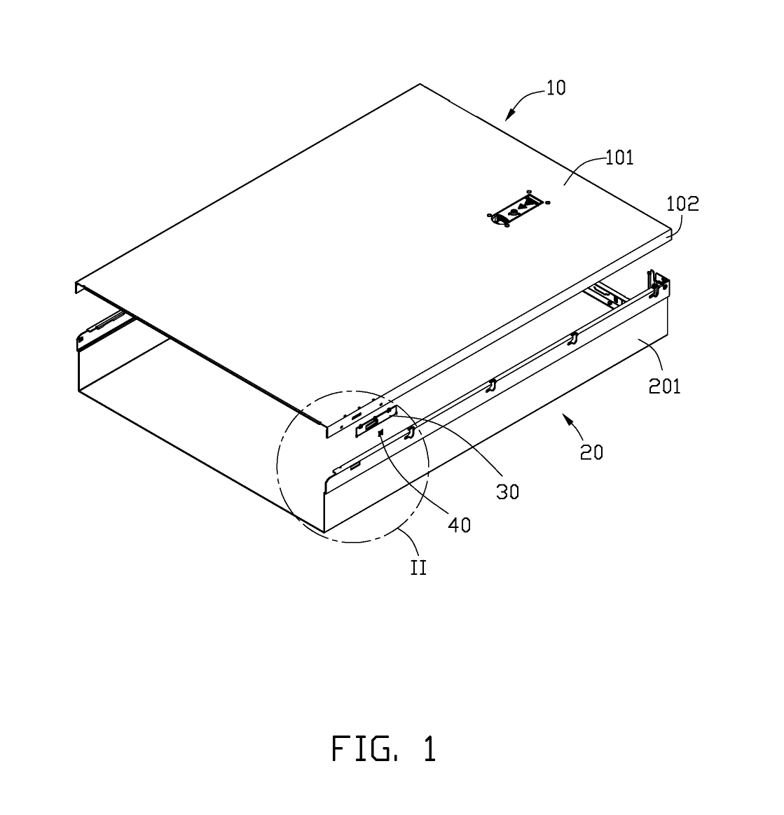

FIG. 1.

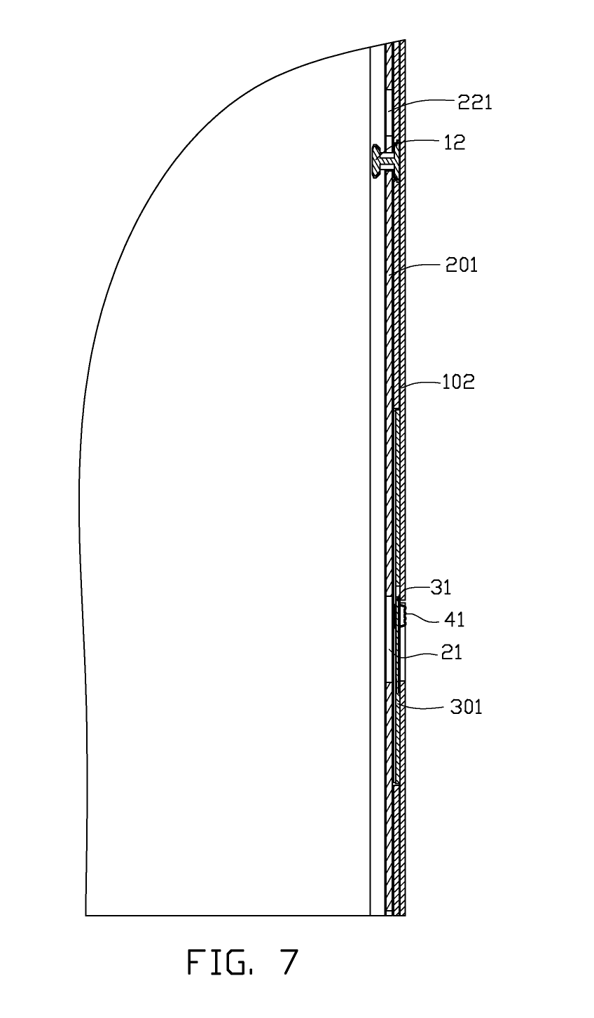

FIG. 6 is a cross sectional view of FIG. 5, taken along a line VI-VI, showing the operation member in a locked position.

FIG. 7 is similar to FIG. 6, but showing the operation member in an unlocked position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

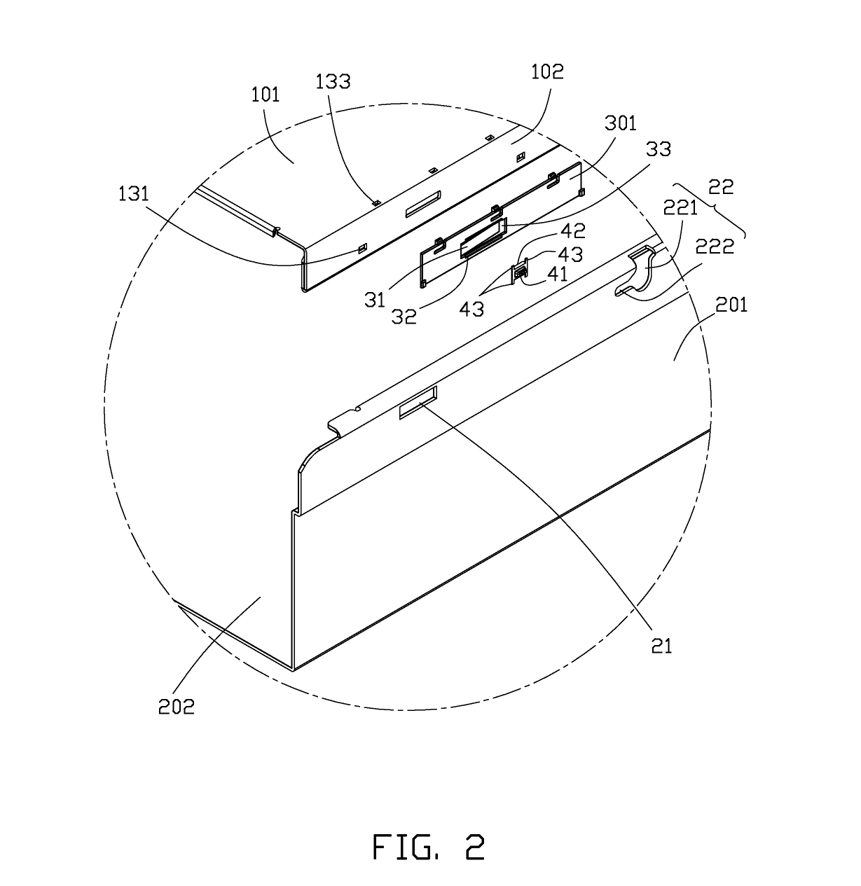

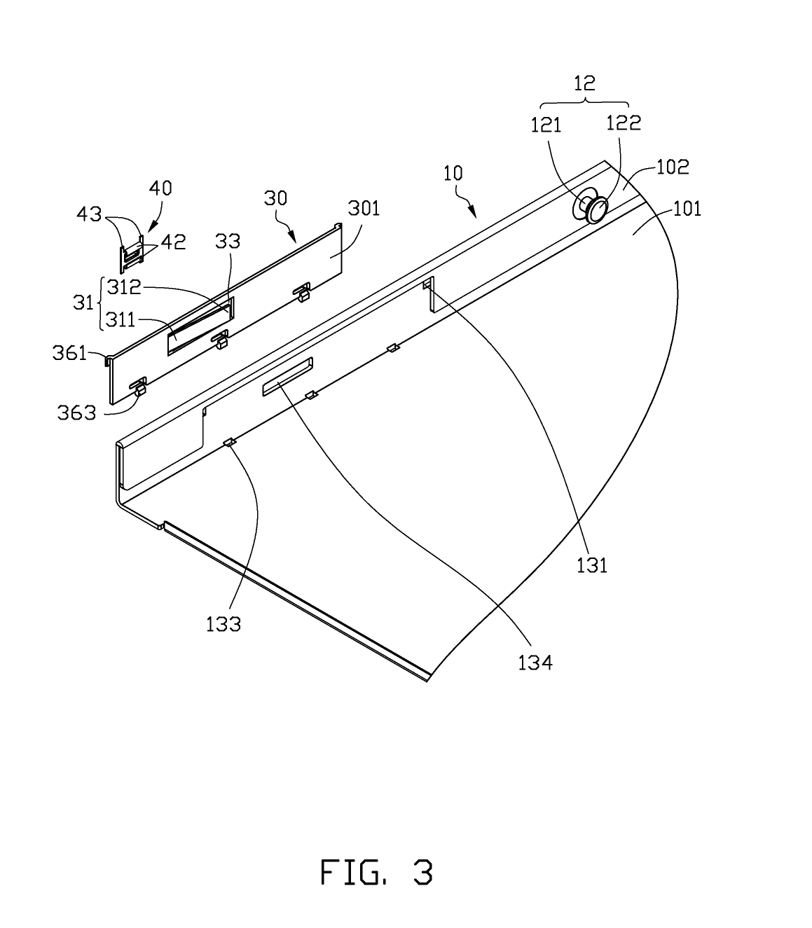

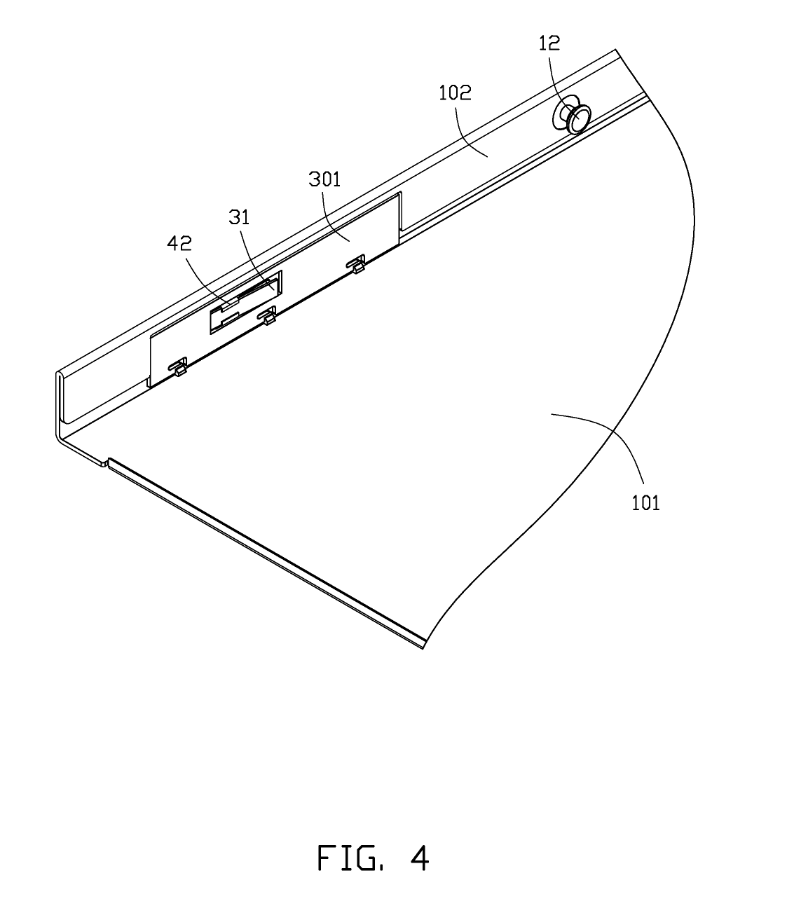

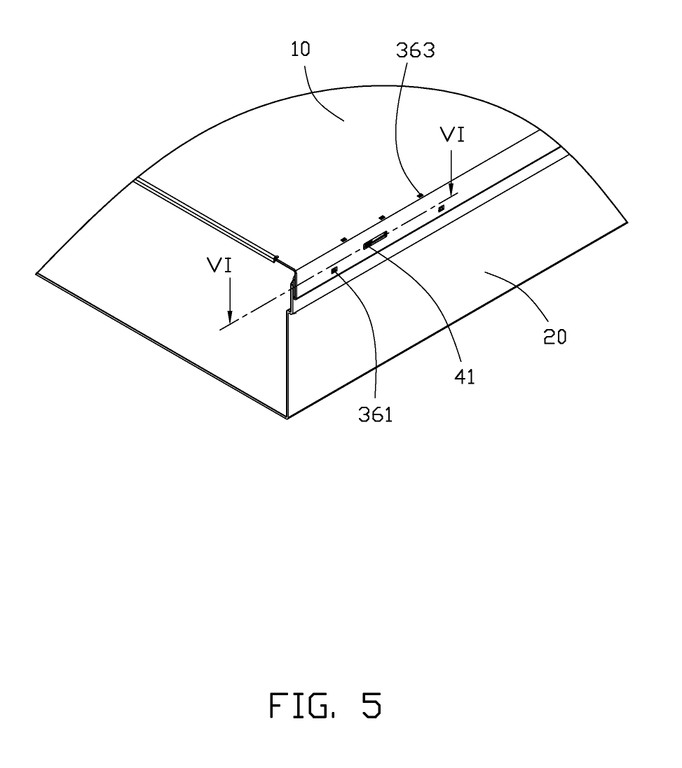

FIGS. 1-3 show one embodiment of an electronic device enclosure. The electronic device enclosure includes a housing 20, a cover 10 secured to the housing 20, a plurality of installation members 12, a blocking member 30, and an operation member 40. The housing 20 defines a plurality of installation holes 22 corresponding to the installation members 12.

The blocking member 30 is configured for preventing the installation members 12 from disengaging from the installation holes 22. The blocking member 30 includes a mounting plate 301, a blocking piece 31, two first blocking portions 361, and two second blocking portions 363. The mounting plate 301 defines a through hole 33. In one embodiment, the through hole 33 is rectangular. The blocking piece 31 includes a connecting end 311 and a movable end 312. The connecting end 311 extends from a first side edge of the through hole 33. The movable end 312 extends slantingly from the connecting end 311 relative to the mounting plate 301. The movable end 312 is elastically deformable relative to the mounting plate 301 to be received in the through hole 33 around the connecting end 311. A sliding slot 32 extends from each of a top edge and a bottom edge of the through hole 33. A length of the sliding slot 32 is less than a length of the through hole 33. The first blocking portions 361 extend from opposite side edges of the mounting plate 301. The second blocking portions 363 extend from a bottom edge of the mounting plate 301 and are elastically deformable relative to the mounting plate 301.

The operation member 40 can include two hooks 42, two pairs of limiting portions 43, and an operation portion 41. The hooks 42 and the operation portion 41 extend from opposite directions. The hooks 42 engage with a top edge and a bottom edge of the blocking piece 31. The limiting portions 43 slidably engage in the sliding slots 32.

The housing 20 can include a bottom plate 202 and two side plates 201 perpendicularly extending from the bottom plate 202. The installation holes 22 can be defined in one of the side plates 201 in a line substantially parallel to the side plate 201. Each of installation hole 22 includes a guiding portion 221 and a locking portion 222 communicating with the guiding portion 221. The side plate 201 further defines two positioning holes 21 corresponding to the blocking piece 31.

The cover 10 can include a top wall 101 and two sidewalls 102 perpendicularly extending from the top wall 101. Each installation member 12 includes a securing portion 121 and an installation portion 122 connected to the securing portion 121. Each sidewall 102 defines two first securing holes 131 corresponding to the first blocking portions 361 and a sliding hole 134 corresponding to the operation portion 41. A width of the sliding hole 134 is substantially the same as a width of the operation portion 41. The top wall 101 defines a plurality of second securing holes 133 corresponding to the second blocking portions 363.

In one embodiment, each of the blocking member 30 and the operation member 40 is made of plastic.

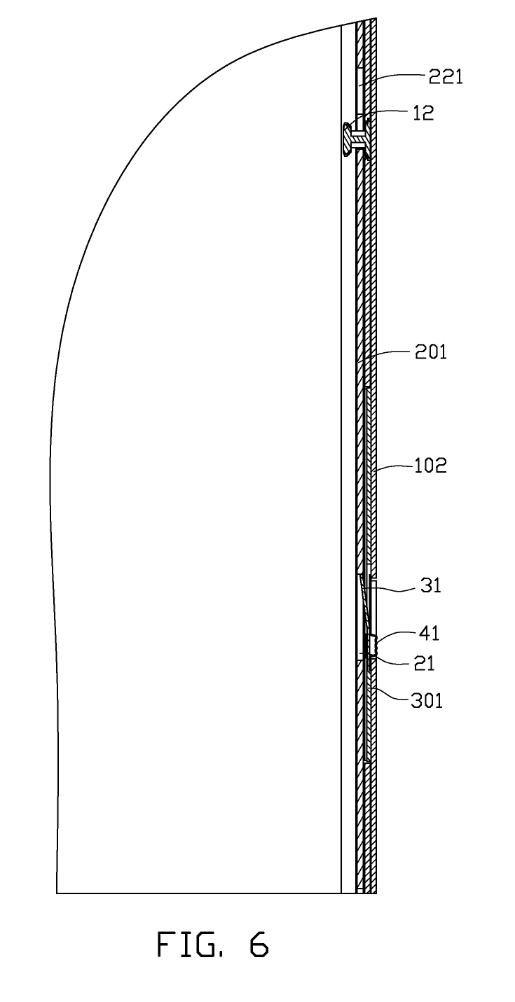

FIGS. 4-7 show that when an e-device enclosure is in an assembled configuration, the hooks 42 of the operation member 40 extend through the through hole 33 to engage the top edge of the bottom edge of the blocking piece 31 therebetween. The limiting portions 43 are slidably received in the sliding slots 32. Thus, the operation member 40 is rotatably mounted to the mounting plate 301. A sliding direction of the operation member 40 is substantially perpendicular to the side edge of the through hole 33, from which the connecting end 311 of the blocking piece 31 extends. The first blocking portions 361 are engaged in the first securing holes 131. The second blocking portions 363 are aligned with the second securing holes 133. The mounting plate 301 is pressed to elastically deform the second blocking portions 363. The second blocking portions 363 rebound to be engaged in the second securing holes 133 after extending out of the second securing holes 133, to secure the blocking member 30 to the sidewall 12. The operation member 40 and the blocking member 30 are located between the sidewall 102 and the side plate 201. The operation portion 41 extends out of the sliding hole 134. The operation member 40 is slidable relative to the blocking member 30 by sliding the operation portion 41 in the sliding hole 134.

When the cover 10 is in an assembled configuration, the operation portion 41 is pushed to slide the operation member 40 relative to the blocking member 30 to a locked position, where the limiting portion 43 abuts a first end of the sliding slot 32 adjacent to the connecting end 311, the hooks 42 are adjacent to the connecting end 311, and the movable end 312 slants relative to the mounting plate 301. The cover 10 is placed above the housing 20 to align the installation members 12 with the guiding portions 221. The cover 10 is pushed along a first direction, substantially perpendicular to the bottom plate 202, to move the installation portions 122 in the guiding portions 221. The sidewall 102 abuts the side plate 201. The blocking piece 31 is pressed to be received in the through hole 33. The cover 10 is pushed along a second direction, substantially parallel to the bottom plate 202, to move the installation portions 122 to the locking portions 222 from the guiding portions 221. The blocking member 30 is moved together with the cover 10 until the blocking piece 31 is aligned with the positioning hole 21. The blocking piece 31 is released, and the movable end 312 rebounds to resist an edge of the positioning hole 21 from the through hole 33, preventing the installation members 12 from moving along a third direction, which is opposite to the second direction, to disengage from the installation holes 22. Thus, the cover 10 is secured to the housing 20.

When the cover 10 is in a disassembled configuration, the operation portion 41 is pushed to slide the operation member 40 relative to the blocking member 30 to an unlocked position, where the limiting portion 43 abuts a second end of the sliding slot 32 adjacent to the movable end 312, the hooks 42 are adjacent to the movable end 312, the movable end 312 is received in the through hole 33, and the blocking piece 31 is coplanar with the mounting plate 301. When the operation portion 41 is slid from the locked position to the unlocked position, the limiting portion 43 is slid from the first end of the sliding slot 32 to the second end of the sliding slot 32, and the hooks 42 move from the connecting end 311 to the movable end 312, causing the movable end 312 to be elastically deformed towards the sidewall 102 to be received in the through hole 33. The cover 10 can be moved along the third direction to disengage the installation members 12 from the locking portions 222, and then the cover 10 can be moved upward to be removed from the housing 20.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure. The embodiments discussed herein do not limit the following claims.

What is claimed is:

1. An electronic device enclosure comprising:
a housing defining an installation hole and a positioning hole;
a cover secured to the housing and comprising an installation member engaged in the installation hole;
a blocking member secured to the cover and comprising a blocking piece; and
an operation member slidably mounted to the blocking member;
wherein the operation member is slidable relative to the blocking member between a locked position, in which the blocking piece extends into the positioning hole and resists an edge of the positioning hole, preventing the installation member from disengaging from the installation hole, and an unlocked position, in which the blocking piece is disengaged from the positioning hole, allowing the installation member to be disengaged from the installation hole.

2. The electronic device enclosure of claim 1, wherein the blocking piece is elastically deformable, and the operation member elastically deforms the blocking piece when being slid, causing the blocking piece to disengage from the positioning hole.

3. The electronic device enclosure of claim 1, wherein the blocking member comprises a mounting plate, and the mounting plate defines a through hole; the blocking piece comprises a connecting end extending from a side edge of the through hole and a movable end extending slantingly from the connecting end.

4. The electronic device of claim 3, wherein when the operation member is in the locked position, the movable end extends out of the through hole; and when the operation member is in the unlocked position, the movable end is received in the through hole, and the blocking piece is coplanar with the mounting plate.

5. The electronic device enclosure of claim 3, wherein the operation member comprises two hooks, and the two hooks engage opposite edges of the blocking piece therebetween.

6. The electronic device enclosure of claim 5, wherein the operation member further comprise a limiting portion, a sliding slot extends from a bottom edge of the through hole, and the limiting portion is slidably received in the sliding slot; and the bottom edge of the through slot is adjacent to the side edge of the through hole.

7. The electronic device of claim 6, wherein an extending direction of the sliding slot is substantially parallel to the side edge of the through hole.

8. The electronic device of claim 6, wherein a length of the sliding slot is less than a length of the through hole.

9. The electronic device of claim 6, wherein when the operation member is in the locked position, the limiting portion abuts a first end of the sliding slot and adjacent to the connecting end, the limiting portion abuts a first end of the sliding slot and is adjacent to the connecting end; and when the operation member is in the unlocked position, the limiting portion abuts a second end of the sliding slot and is adjacent to the movable end.

10. The electronic device of claim 5, wherein the operation member further comprises an operation portion extending opposite to the hooks, the cover further defines a sliding hole, and the operation portion is slidably received in the sliding hole; and the operation portion is slidable in the sliding hole to slide the operation member relative to the blocking member.

11. An electronic device enclosure comprising:
a housing comprising a side plate, and the side plate defining an installation hole and a positioning hole;
a cover secured to the housing and comprising a sidewall and an installation member secured to the sidewall and engaged in the installation hole;
a blocking member secured to the cover and comprising a blocking piece; and
an operation member slidably mounted to the blocking member;
wherein the operation member and the blocking member are located between the sidewall and the side plate; the blocking piece slants relative to the side plate and extends into the positioning hole; and the operation member is slidable relative to the blocking member disengage the blocking piece from the positioning hole, allowing the installation member to be disengaged from the installation hole.

12. The electronic device enclosure of claim 11, wherein the blocking piece is elastically deformable, and the operation member elastically deforms the blocking piece when being slid, causing the blocking piece to disengage from the positioning hole.

13. The electronic device enclosure of claim 11, wherein the blocking member comprises a mounting plate, and the mounting plate defines a through hole; the blocking piece comprises a connecting end extending from a side edge of the through hole and a movable end extending slantingly from the connecting end.

14. The electronic device of claim 13, wherein when the blocking piece is slantingly engaged in the positioning hole, the movable end extends out of the through hole; and when the blocking piece disengaged from the positioning hole, the movable end is received in the through hole, and the blocking piece is coplanar with the mounting plate.

15. The electronic device enclosure of claim 13, wherein the operation member comprises two hooks, and the two hooks engage opposite edges of the blocking piece therebetween.

16. The electronic device enclosure of claim 15, wherein the operation member further comprise a limiting portion, a sliding slot extends from a bottom edge of the through hole, and the limiting portion is slidably received in the sliding slot; and the bottom edge of the through slot is adjacent to the side edge of the through hole.

17. The electronic device of claim 16, wherein an extending direction of the sliding slot is substantially parallel to the side edge of the through hole.

18. The electronic device of claim 16, wherein a length of the sliding slot is less than a length of the through hole.

19. The electronic device of claim 16, wherein when the operation member is in the locked position, the limiting portion abuts a first end of the sliding slot and adjacent to the connecting end, the limiting portion abuts a first end of the sliding slot and is adjacent to the connecting end; and when the operation member is in the unlocked position, the limiting portion abuts a second end of the sliding slot and is adjacent to the movable end.

20. The electronic device of claim 15, wherein the operation member further comprises an operation portion extending opposite to the hooks, the cover further defines a sliding hole, and the operation portion is slidably received in the sliding hole; and the operation portion is slidable in the sliding hole to slide the operation member relative to the blocking member.
